(19) United States
(12) Patent Application Publication
(10) Pub. No.: US 2023/0394350 A1
(43) Pub. Date: Dec. 7, 2023

(54) QUANTUM ERROR CORRECTION

(71) Applicant: University of Technology, Sydney, Ultimo (AU)

(72) Inventors: Michael John Bremner, Ultimo (AU); Simon Devitt, Ultimo (AU); Alexis Shaw, Ultimo (AU)

(73) Assignee: University of Technology, Sydney, Ultimo (AU)

(21) Appl. No.: 18/033,313

(22) PCT Filed: Sep. 30, 2021
(86) PCT No.: PCT/AU2021/051138

§ 371 Date: Apr. 21, 2023

(30) Foreign Application Priority Data
Oct. 23, 2020 (AU) 2020903848
Apr. 30, 2021 (AU) 2021901279

(51) Int. Cl. G06N 10/70; G06N 10/20; G06N 10/40

(52) U.S. Cl. CPC G06N 10/70; G06N 10/20; G06N 10/40

(57) ABSTRACT

This disclosure relates to a quantum processor comprising multiple patches of digital qubits and a quantum bus of digital qubits. The quantum bus is configured to connect the multiple patches of digital qubits and to transmit quantum information constituting long-range interactions between the patches of digital qubits. The quantum processor is controlled by a first method of error correction on each of the patches connected by the bus to reduce a relatively high error rate in the digital qubits to a relatively low error rate of each patch, and by a second method of error correction on the multiple patches to correct the relatively low error rate. The number of patches can be increased to increase the distance of the second method and therefore reduce the final error rate. Due to the quantum bus, the patches can be arranged such that there is sufficient space between them for control circuitry.

### CROSS-REFERENCE TO RELATED APPLICATIONS

The present application claims priority from Australian provisional application 2020903848 and Australian provisional application 2021901279, the contents of which are incorporated herein by reference in their entirety.

### TECHNICAL FIELD

This disclosure relates to a quantum processor and a method for operating a quantum processor. In particular, it relates to the layout design and physical architecture of a quantum processor that supports error correction in current quantum technology.

### BACKGROUND

Quantum computers are difficult to build due to the inherent instability of quantum information in quantum physical systems (‘qubits’). One approach that has been suggested is the surface code, which is a quantum error correction code. The surface code builds on an array of tightly packed qubits. In some implementations each qubit has a size of only about 100 nm×100 nm or even less. The distance between qubits is typically within this size to enable interactions between neighbouring qubits. As a result, the overall area of the array that is used for the surface code is small. However, each qubit needs to be connected to control circuitry by ‘wires’, which are implemented as metal lines across a silicon substrate, for example. The small size of the qubit array means that connecting wires also need to be tightly packed. However, with the current hardware technology, it is difficult to manufacture wires that are small enough to connect all qubits and in particular those qubits that are in the middle of the qubit array.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each of the appended claims.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### SUMMARY

This disclosure provides an architecture for a quantum processor that facilitates manufacturing of the quantum processor using current hardware technology. In particular, the proposed architecture comprises small patches of qubits that are controlled by a surface code. The patches are connected by a quantum bus to enable long-range interactions between qubits of different patches. A second error correction code is performed on top of the surface code using the patches as logical qubits.

A quantum processor comprises:
multiple patches of digital qubits; and
a quantum bus of digital qubits, configured to connect the multiple patches of digital qubits and to transmit quantum information constituting long-range interactions between the patches of digital qubits, wherein
the quantum processor is controlled by a first method of error correction on each of the patches connected by the bus to reduce a relatively high error rate in the digital qubits to a relatively low error rate of each patch, and by a second method of error correction on the multiple patches to correct the relatively low error rate.

It is an advantage that the quantum processor comprises patches of qubits, which are controlled by a first method of error correction and then by a second method of error correction on the patches. This way, the number of patches can be increased to increase the distance of the second method and therefore reduce the final error rate. Advantageously, due to the quantum bus, the patches can be arranged such that there is sufficient space between them for control circuitry. This is an advantage over large square arrays of qubits, which are difficult to connect in practice.

The quantum bus may have a constant width of qubits.

The patches may be square.

The multiple patches may form multiple arrays of more than one patch each connected by the quantum bus. The multiple arrays may be linear arrays. Each linear array may have an identical width. Each linear array may have an array width defined by one of the multiple patches and the quantum bus, the array width being 15 or 20. Each linear array may have an array length defined by more than one of the multiple patches and the quantum bus, the array length being 120 or 160.

The quantum processor may further comprise an area between the multiple patches comprising connections to the digital qubits of the multiple patches.

The digital qubits of the bus may be controlled by the first method of error correction. The first method of error correction may comprise a surface code. The second method of error correction may comprise a block code. The block code may comprise a Steane code.

The relatively low error rate may be less than 10⁻⁵. The relatively low error rate may be more than 10⁻⁸. Correcting the relatively low error rate may results in a corrected error rate of less than 10⁻⁹.

The quantum processor may further comprise control circuitry to perform the first method of error correction and the second method of error correction.

The patches may be rectangular and may have a first dimension that is greater than a second dimension to reduce the error rate of a first type of error, associated with the first dimension, to a greater degree than the error rate of a second type of error, associated with the second dimension.

The first method of error correction may be an asymmetric surface code to reduce the error rate of the first type of error to a greater degree than the error rate of the second type of error.

The second method of error correction may be a repetition code to reduce the error rate of the second type of error.

The second method of error correction may reduce the error rate of only the second type of error.

The first type of error may be one of a bit flip error and a phase flip error and the second type of error may be another one of a bit flip error and a phase flip error.

There is provided a method for operating a quantum processor, the quantum processor comprising multiple patches of digital qubits and a quantum bus of digital qubits, configured to connect the multiple patches of digital qubits and to transmit quantum information constituting long-range interactions between the patches of digital qubits, the method comprising:
applying a first method of error correction to each of the patches connected by the bus to reduce a relatively high error rate in the digital qubits to a relatively low error rate of each patch; and
applying a second method of error correction to the multiple patches to correct the relatively low error rate.

A method for manufacturing a quantum processor comprises:
creating multiple patches of digital qubits to form a first array of a number of patches;
connecting the multiple patches of the first array by a quantum bus of digital qubits, configured to connect the multiple patches of digital qubits and to transmit quantum information constituting long-range interactions between the patches of digital qubits;
creating multiple further arrays having an identical number of patches as the first array;
connecting the multiple further arrays to the first array by the quantum bus;
creating control circuitry to control the quantum processor by a first method of error correction on each of the patches connected by the bus to reduce a relatively high error rate in the digital qubits to a relatively low error rate of each patch, and by a second method of error correction on the multiple patches to correct the relatively low error rate.

A number of the multiple further arrays may be based on a desired error rate after correction of the relatively low error rate.

### BRIEF DESCRIPTION OF DRAWINGS

An example will now be described with reference to the following drawings:

FIG. 1 illustrates a quantum processor.

FIG. 2 illustrates the connectivity of a distance-7 rotated surface code patch.

FIG. 3 illustrates stabilizers for a distance 7 rotated surface code.

FIG. 4a illustrates a square surface-code patch.

FIG. 4b illustrates a rectangular surface-code patch including a single qubit.

FIG. 5 illustrates a rectangular surface-code patch including two qubits.

FIG. 6 illustrates an example structure of square patches in a linear array.

FIG. 7 illustrates an example structure of rectangular patches in a linear array.

FIG. 8 illustrates an example of two linear arrays of square patches arranged perpendicularly to each other.

FIG. 9 illustrates a parity measurement gadget.

FIG. 10 illustrates results of the proposed method.

FIG. 11 illustrates a method for operating a quantum processor.

FIG. 12 illustrates a method for manufacturing a quantum processor.

FIG. 13 illustrates a rectangular planar surface code with a d_z=3 and a d_x=7, comprising an array of physical qubits 13 deep and 5 wide.

FIG. 14 illustrates a Z-stabiliser quantum circuit for use with the surface code from FIG. 13.

FIG. 15 illustrates a X-stabiliser quantum circuit for use with the surface code from FIG. 13.

FIG. 16 illustrates a quantum circuit to perform a parity check.

FIG. 17 illustrates a sequence of operations for error correction.

### DESCRIPTION OF EMBODIMENTS

### Quantum Processor

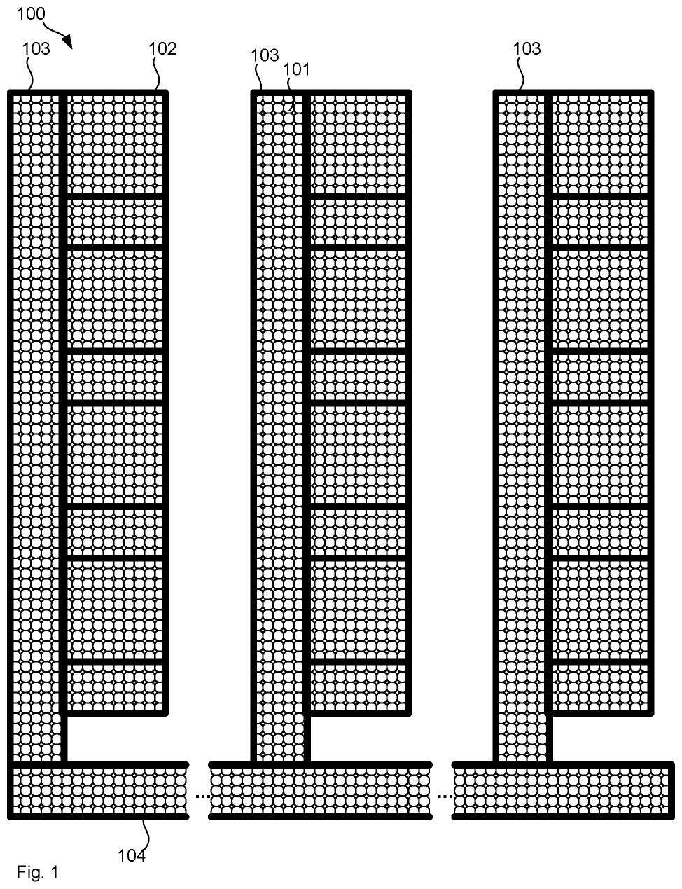

FIG. 1 illustrates a quantum processor 100 comprising multiple digital qubits, which are shown as small, rounded squares, such as example qubit 101. Digital qubits may be qubits representing quantum information in a digital sense, such as electron or nucleus spins, or superconducting digital qubits using Josephson Junctions. Digital qubits are in contrast to analog qubits which are used in adiabatic quantum computers. Digital qubits may provide different functionalities, such as data qubits or ancilla qubits.

The multiple qubits are arranged in multiple patches of digital qubits, such as example patch 102. Each patch can also be referred to as a subset, group or area of qubits. The bold lines in FIG. 1 illustrate logical groups of qubits and do not necessarily represent hardware features. Patches of qubits are shown as square patches in FIG. 1 for clarity although rectangular patches and other shapes are possible. In the example of FIG. 1, the patches have a size of 10×10 qubits, which means the bold square indicating patch 102 includes 100 rounded squares (i.e. qubits).

Quantum processor 100 also comprises a quantum bus of digital qubits, comprising an intra-qubit bus 103 and a main quantum bus 104. The quantum bus 103/104 connects the multiple patches 102 of digital qubits and to transmit quantum information constituting long-range interactions between the patches of digital qubits. When reference is made herein to the “quantum bus”, this refers to the intra-qubit bus 103 and the quantum bus 104 together as one “bus”.

The quantum processor 100 is controlled by a first method of error correction on each of the patches 102 connected by the bus, such as a surface code. The surface code reduces a relatively high error rate in the digital qubits to a relatively low error rate of each patch. Quantum processor 100 is further controlled by a second method of error correction on the multiple patches, such as a block code or Steane code. The block code corrects the relatively low error rate of the patches to ultimately provide an error rate that is sufficiently low for a desired operation of the quantum processor 100.

### Quantum Bus

The quantum bus 103/104 can be used to perform fault-tolerant long-range parity-check operations. Long-range parity checks provide a recipe for performing arbitrary length fault-tolerant parity checks. Operating the quantum bus 103/104 may comprise the following steps:
1. Produce a Greenberger-Horne-Zeilinger state (GHZ state) with N data qubits (four time steps), and keep it corrected against bit-flip errors (d cycles).
2. Perform a transversal CNOT operation between all connected surface code patches and their part of the GHZ-state. The CNOTs can be applied in parallel and, thus, require only one time step.
3. Without the measurement of any further stabilizers, all data qubits of the complete chain of the GHZ-state are measured (one time step).
4. Repeat steps 1-3 for d times, and use majority voting over the individual measurement results to obtain the error-corrected measurement result in total time O(d²).

In the example of FIG. 1, the main quantum bus 104 is five qubits wide but other widths are equally possible. Further, as can be seen, the quantum bus has a constant width, which means the bus has a width of five qubits across the quantum processor 100. The main quantum bus 104 connects the columns, which are also referred to as “arrays” or, in the example of FIG. 1, “linear arrays” because all patches of the array are arranged in one line next to one another. Therefore, each linear array has an identical width and in this example, is 15 physical qubits wide, including the 10 patch qubits and 5 bus qubits. The width of an array is defined by the size of one patch and the width of the quantum bus. In FIG. 1 each linear array is 75 physical qubits long, so has a dimension of 15×75. Other configurations may be 15×120 or 20×160 and each column may have 7 or 15 logical qubits (i.e. patches), noting that only four patches per column are shown in FIG. 1. Exact dimensions may vary and are dependent on code choices and design choices which may vary.

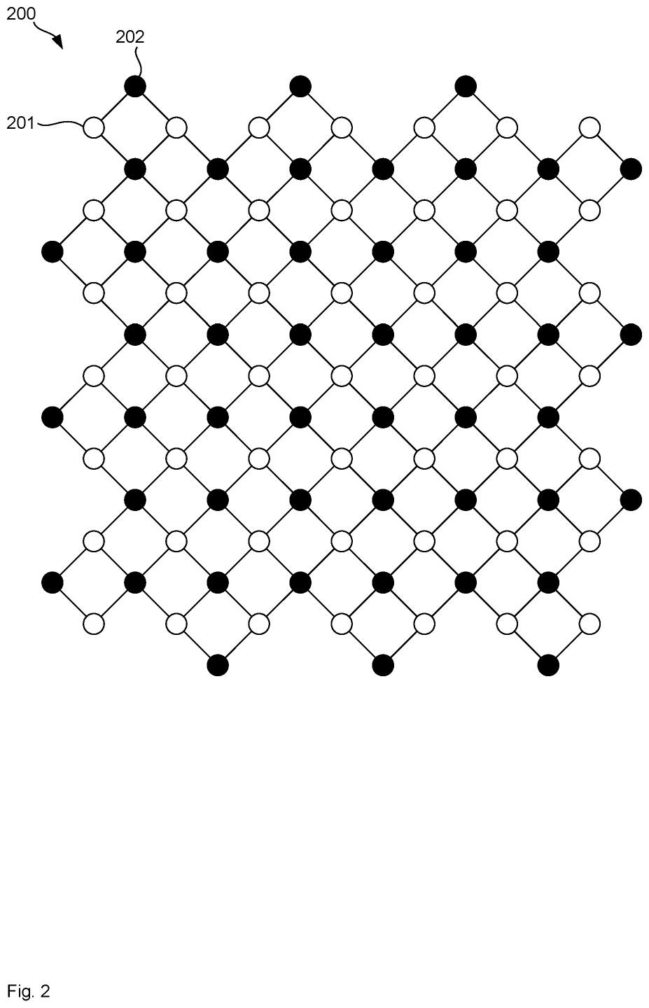

In one example, the dimensions depend on the specifics of the second level code and the size of each patch 102. In particular, the width of patches 102 may be twice the code distance. So the example of FIG. 1 shows a distance 5 code with a patch width of 10, noting that FIG. 1 shows non-rotated surface code patches, while FIG. 2 shows a rotated structure. In FIG. 1, the bus is 5 qubits wide, which is the same as the code distance in this example. While FIG. 1 only shows 4 patches in each linear array, other implementations can have more patches, such as 11 (Steam code, 7+2+2=11), or 19 ([[15,7,3]] code, 15+2+2=19) patches for each linear array, for example. Other configurations of the codes can also be used. The summations include ancilla qubits for syndrome extraction and CNOT gadget implementation. The notation [[n, k, d]] denotes a quantum error correcting code that encodes k logical qubits into n physical qubits with a quantum code distance d. So, a [[15, 7, 3]] code encodes 7 logical qubits into 15 physical qubits at distance 3 and corrects at least 1 quantum error. In other words, each linear array represents an output of the selected code plus ancilla qubits/gadgets (‘output’ here means the result of the multiplication of the input with the code matrix as in classical information theory). For example, if the code encodes 7 logical qubits into 15 physical qubits, there would be one patch for each physical qubit plus ancilla/gadget qubits. That is, each patch represents one qubit (or ancilla/gadget) of the second level code and each linear array represents a code output. Further, if a larger first level code distance is required, additional physical qubits can be added to the design of each patch, such as in the distance 11 code presented below.

It is noted that the width of each logical qubit 102 determines the maximum possible distance of the surface code error correction. In other words, wider logical qubits provide for better error correction while narrower logical qubits provide for worse error correction. The surface error code can be applied on individual physical qubits having a relatively high error rate. On the other hand, block codes, such as Steane (7-qubit) code [[7,1,3]] or the [[15,7,3]] code and other Calderbank-Shor-Steane (CSS) codes are applicable for lower error rates. Therefore, the width of each logical qubit is chosen such that the resulting error rate from the surface code is just low enough for the application of a block code on a second level of error correction to provide a an error rate low enough for the target quantum calculation. In some examples, the width is 15 or 20 physical qubits but other values may be chosen as well. While wider logical qubits would result in a lower error rate at the first level, the manufacturing cost would rise without direct benefit since the second level error correction code can correct the remaining error as long as the width is above the threshold.

Again, the horizontal region 104 at the bottom is a master bus system that can then be used to interact logical qubits at the highest level of encoding. This allows for the interaction of each logical qubit and the execution of algorithms. The bus is again fully error corrected, has a finite width and a length that is proportional to the number of “forks”/arrays of logical qubits in the entire computer.

The physical placement of the logical qubits and the bus system allows the chipset to be highly distributed. White space in FIG. 1 represents regions where control electronics can be placed and wired to each physical qubit in the system for operation and control of the computer 100. The size and density of these control electronics will determine the exact geometric layout of the fork and bus system that comprises the chipset.

### Error Correction

Most current architectures for quantum computation suppose that computation will occur using a large 2D square lattice of qubits, with single qubit gates and nearest neighbour interactions. In these architectures the logical qubits are usually represented using the surface code on roughly square patches where one dimension determines the susceptibility to X-type errors, and the other determines the susceptibility to Z-type errors, (more strictly the minimum Manhattan distance between the rough and smooth boundaries determines the code distance, and this is minimised for a rotated square.) Many quantum computations require a logical error rate

$$∝ \frac{1}{A}$$

where A is the time-space volume of the logical computation, thus for longer and larger computations larger logical volumes are used, and so higher levels of error correction, for example it is estimated that to solve factoring on a 2048-bit number will require a code of distance 27, giving a logical error rate of 10⁻¹⁵ using a more recent estimate of scaling which may be achievable with a code distance of 23.

However for many architectures the per-qubit cost and difficulty grows (often non-linearly) with the distance between a given qubit and the edge of the array due to qubit control interconnect costs and challenges. Therefore, this disclosure provides a scalable architecture that is able to perform computations with a much lower width than this, at the cost of additional time and qubits.

This disclosure provides a hybrid multi-layer error correcting code, there are two main layers:
1. A first level code being a base rotated surface code with code distance d. This code uses rotated 2-D square lattice patches 102 of qubits, which are then used as a substrate for the second layer of code. Multi-qubit operations occur using surface code bus 103/104. The distance d is chosen to be as low as possible for the second level code to get sufficient error reduction as described above. In one example, the first level code reduces the error rate to between 10⁻⁵ and 10⁻⁷.
2. A second level code that provides qubits at the required error rate of the final logical qubits. This code may be a block code. The surface code bus 103/104 provides a method for long-distance interactions that enables any block code to be implemented without moving the qubits to enable interaction. In one example, the error rate after applying the second level code is less that 10⁻⁹.

If the level 2 code is a singly concatenated [[7,1,3]] Steane code, and a distance-11 base layer, the logical error rate may be better than 10⁻¹⁵.

### Surface Code Layer

In one example, the first level code is implemented using a collection of distance-d, rotated surface code patches, these are adjacent on at least two edge segments to a surface code bus 103/104. This bus in some implementations may be implemented by a folded surface code bus as shown in FIG. 1 with inter-qubit bus 103 and main bus 104, together referred to as “bus”. The patches 102 are the first layer of logical qubits or L₁, which are then used as a substrate for the second layer.

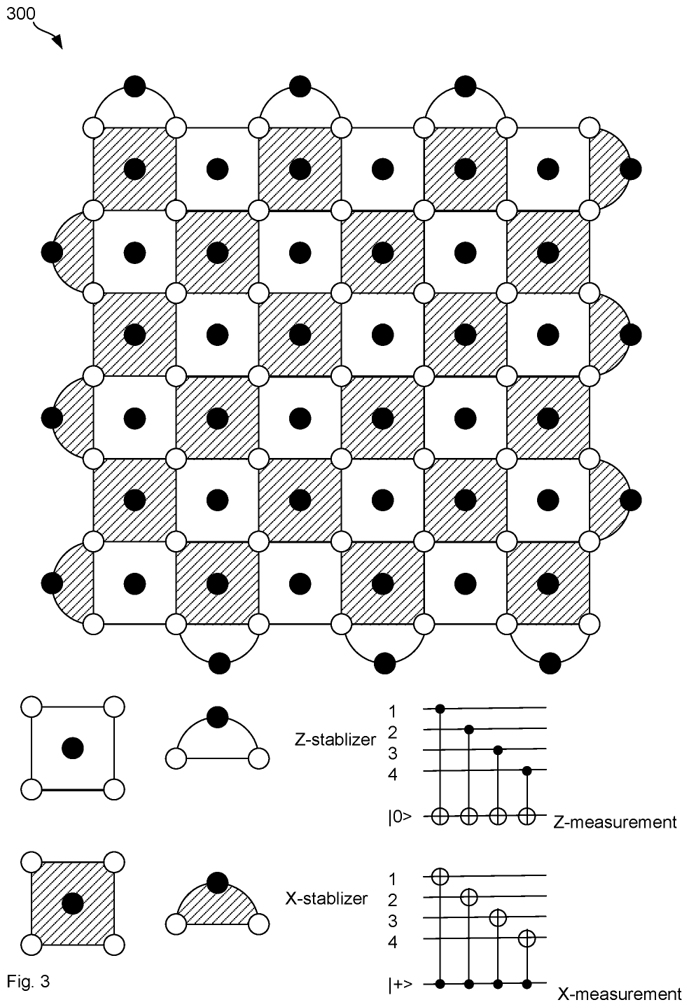

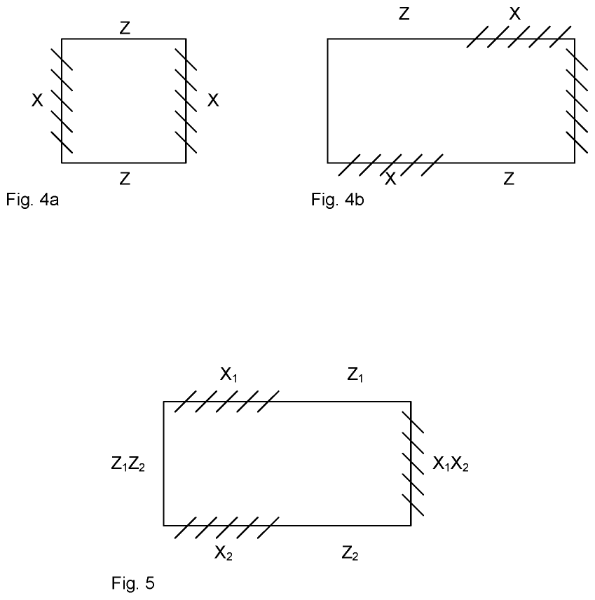

A rotated surface code operates on a square lattice of qubits similar to that in FIG. 2. In this figure the open circles are data-qubits and the solid dots are measurement ancillary qubits (ancilla), and solid lines represent pairs of qubits that are able to interact directly. FIG. 3 is an example of the layout of stabiliser codes, with the hatched regions each representing a Z stabiliser on the data qubits at its corners and the un-hatched regions representing an X stabiliser on the data qubits at its corners. Logical operators are represented by strings that cross from one boundary to the other. The distance of a surface code is the number of data qubits on the shortest path between two matching edges. These patches can be represented as squares with marked edges (by convention smooth edges are z-edges and x-edges are rough) like in FIGS. 4a, 4b and 5 where rough edges are indicated by diagonal lines and patches may be square, or some other larger shape, patches may contain a single qubit, or if larger may contain multiple qubits. For example, FIG. 4a illustrates square patch containing one qubit, FIG. 4b illustrates a larger patch (double length) containing one qubit, FIG. 5 illustrates a larger patch (double length) containing two qubits ‘1’ and ‘2’.

Single qubit Clifford operations on the base layer proceed by edge-tracking, and two qubit operations are performed using adaptive two qubit parity measurements and corrections, with the possibility of additional logical ancilla. The bus can perform these parity measurements over arbitrary distances fault-tolerantly and so entangling operations (including CNOT gates) can also be performed over arbitrary distances.

Individual surface code patches 102 are connected together by the qubit bus 103/104. The qubit bus can be seen as an extended region of the surface code, similar to the encoded qubit patches 102, but not encoding any information. The bus itself has a fixed width of five qubits, for example, and extends the required length needed to connect encoded qubit regions. The bus is connected to the logical qubit patches by measuring joint operators along the boundaries. This temporarily ‘connects’ the bus to the logical qubits that are interacted. This connection is maintained for multiple cycles of the surface code error-correction, the same number of cycles as the distance of the underlying code, d. This is referred to as a merge operation.

Once the merge operation is complete, qubits along the boundary where the bus is connected to the logical qubit patches are measured. This disconnects the bus from each logical qubit patch and is referred to as a split operation. The combination of the merge and the spilt completes the logical gate between the patches connected by the bus. The bus can facilitate interactions between an arbitrary number of logical patches.

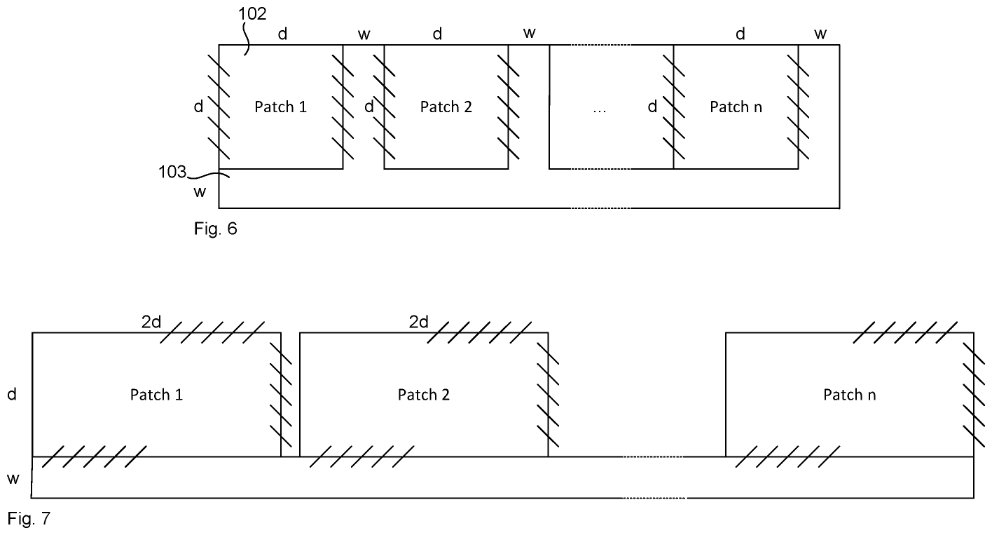

FIG. 6 illustrates an example where square patches of size d qubits are within an array (also referred to as “module”) and connected by a bus of width w qubits in a linear array of patches of constant width w+d, such as with sufficient additional qubits along one rough and one smooth edge of each patch for connection to the qubit bus 103.

FIG. 7 illustrates a further example of a linear array of patches of twice the length, that is, a length of 2d qubits while the bus width remains at w qubits. It is noted that in the example of FIG. 7 the patches have the bottom boundary, that is both rough and smooth, on the bus. That is, the bus only attaches to the one side of the boundary. The gap between qubits is only a small gap, and may even just be a gap of one lattice spacing to enable the logical qubits to be separate and distinct.

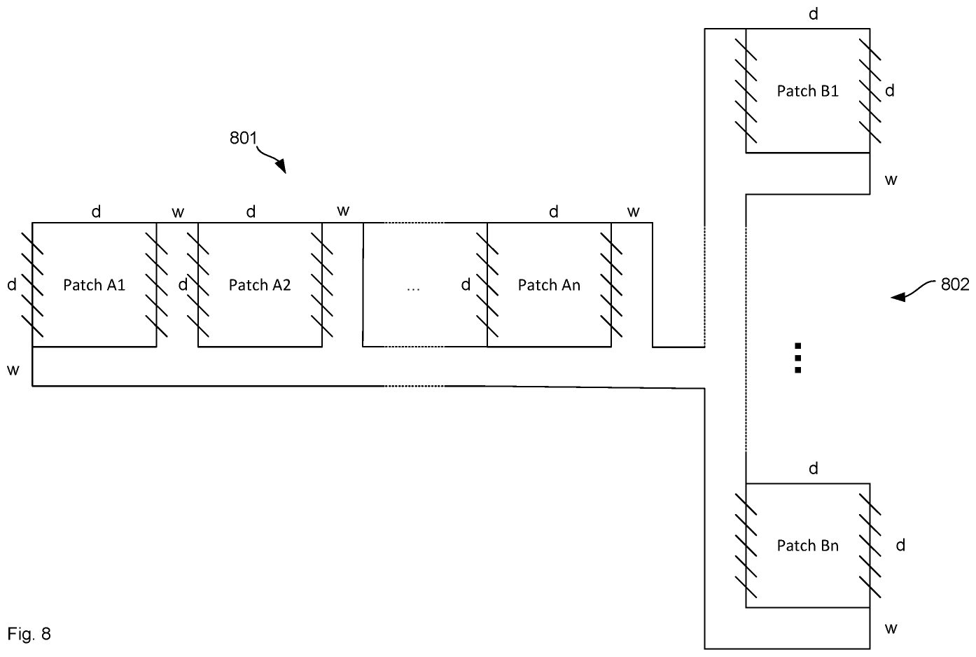

FIG. 8 illustrates a more complex example, where the bus branches out to connect further patches. Here, a first set of patches A1-An are arranged as a first linear sub-array 801, and a second set of patches B1-Bn are arranged as a second linear sub-array 802 that is perpendicular to the first linear sub-array. It is noted that the bus has a width of w across the entire structure. A range of different structures is possible with multiple further sub-arrays which may be perpendicular or arranged at different angles with potentially several branching points. It is noted here again, that each sub-array may represent the output of the level two code plus ancilla qubits as described above.

Patches may be close to each other in a continuous rectangle as shown in FIG. 1 for four patches, or they may be spaced out with long spans of only the bus between them in order to spread out dense areas of qubits. They may be connected in a line or there may be a more elaborate branching pattern to better suit the upper layer coding structures or algorithm. Advantageously, there is sufficient space for the qubit driving circuits or equipment etc. around the patches and bus, and that the distance from any interior qubit and the boundary is below the required limit.

The first level code converts errors at the error rate of the physical qubits to a logical error rate that is sufficiently low for the second level code. With a physical error rate p_{phys}=10⁻³ the logical error rate for a distance-d surface code patch may be estimated as

$${p}_{{L}_{1}} \leq 1 {0}^{- [ \frac{d}{2} + 1 ⌉} .$$

Other estimates put the scaling at

$${p}_{{L}_{1}} \leq 0.3 {( 70 {p}_{phys} )}^{⌊ \frac{d + 1}{2} ⌋}$$

which is slightly tighter. With p_{phys}=10⁻³ these place the logical error rate for a distance-11 surface code patch at 10⁻⁷ and 3.3×10⁻⁸ respectively.

### Second Level Block Code

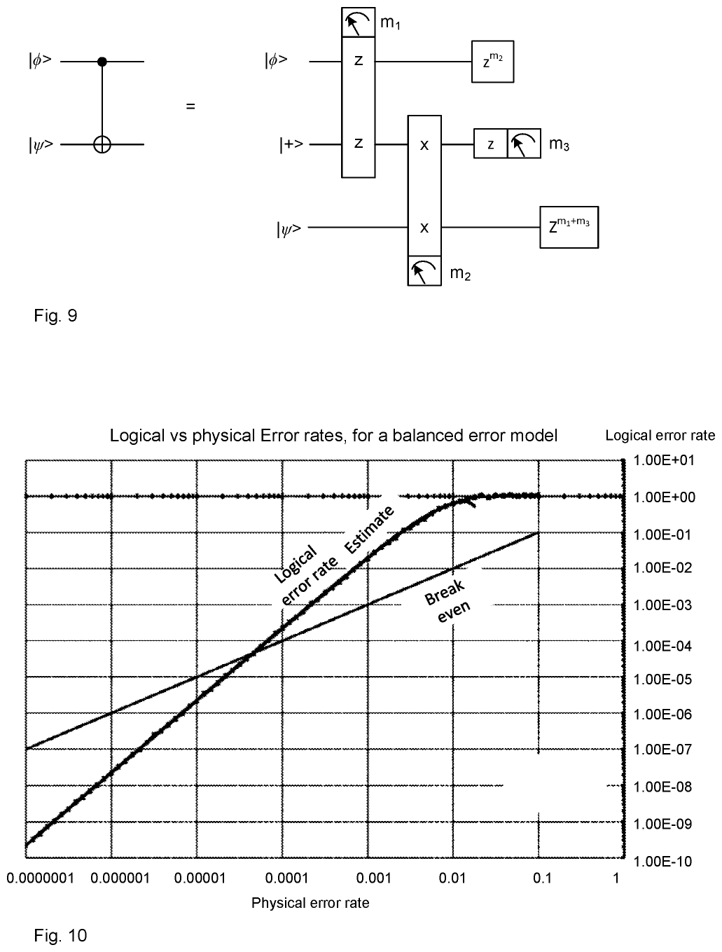

In order to achieve a desired computational fidelity for the final computation, without increasing the patch width further, a second level of quantum error correction code is implemented using the first level (L₁) surface code logical qubits (i.e. patches) as a substrate. The bus architecture enables long-distance gates to be performed natively using long-distance parity measurements and a few additional ancilla (one per parallel CNOT gate). FIG. 9 illustrates a parity measurement gadget that can be used, which is a Pauli measurement CNOT gadget.

This second level code may be any suitable quantum code, such as a block based quantum error correcting code, which are advantageous given the availability of long-distance gates, and parity measurements given by the L₁ code substrate. Examples of codes that may be used are the [[5,1,3]] Shor code, the [[7,1,3]] Steane code, the [[15,7,3]] hamming code, or any of the various quantum low density product codes (LDPC).

### Control Circuitry

Some examples disclosed above utilise codes and other quantum algorithms involving quantum operations. These operations are typically controlled by external control circuitry such as electron spin resonance (ESR) lines or radiation sources, such as microwave or optical sources, or metal pads or lines for static fields, to provide control pulses and fields to the qubits. A classical computer calculates the pulses and other control and read-out signals that result in the desired quantum codes and operations. As such, the classical computer comprises a processor and memory and executes software instructions stored on a non-volatile computer readable medium, which causes the computer to perform the methods described herein. The classical computer is connected to the quantum processor 100, potentially via a signal generator, so that the classical computer can control the quantum processor by applying the first and second methods of error correction to the qubits.

### Method for Operating a Quantum Processor

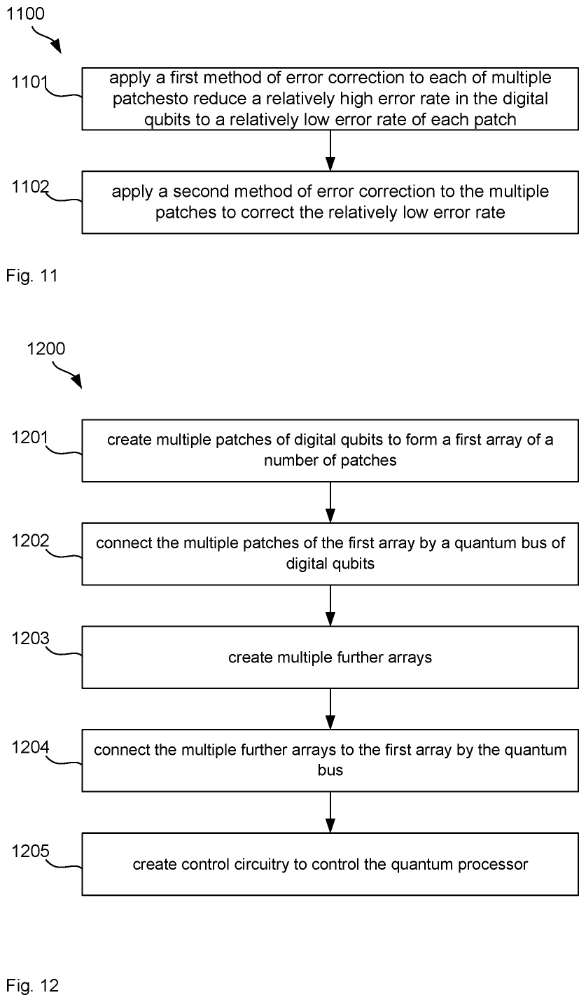

FIG. 11 illustrates a method 1100 for operating quantum processor 100. As described above, the quantum processor comprises multiple patches of digital qubits and a quantum bus of digital qubits. The quantum bus connects the multiple patches of digital qubits and transmits quantum information constituting long-range interactions between the patches of digital qubits. In one example, the method is performed by a classical processor of a classical computer executing a software program.

In that sense, the processor applies 1101 a first method of error correction to each of the patches connected by the bus to reduce a relatively high error rate in the digital qubits to a relatively low error rate of each patch. As explained above, this may involve a surface code that is applied to each patch so as to reduce the natural error rate of the physical qubits to a reduce error rate of a logical qubit formed by a patch.

Further, the processor applies a second method of error correction to the multiple patches to correct the relatively low error rate. This may involve a block code, such as a Steane code, which operates on the logical qubits, as opposed to the physical qubits, to correct the error rate that is remaining from the surface code.

The first method and second method of error correction may be performed sequentially one after another or at the same time. The same method may be applied to all patches or some patches may be subject to the first method while other patches are subject to the second method.

### Method for Manufacturing a Quantum Processor

FIG. 12 illustrates a method 1200 for manufacturing quantum processor 100. Method 1200 comprises creating 1201 multiple patches of digital qubits to form a first array of a number of patches. In this context, “creating” can relate to creating a physical device, such as fabricating qubits including crystal structure creation, implanting dopant atoms and depositing metal wires, for example. However, “creating” can equally relate to creating a digital representation of what is created, such as a digital mask layout for the structure that is to me manufactured or a more high-level and/or more abstracted representation of the device, such as what is shown in FIG. 1.

Method 1200 further comprises connecting 1202 the multiple patches of the first array by a quantum bus of digital qubits. The quantum bus is configured to connect the multiple patches of digital qubits and to transmit quantum information constituting long-range interactions between the patches of digital qubits. In that sense, method 1200 may additionally comprise the step of configuring the quantum bus to connect the multiple patches of digital qubits and to transmit quantum information constituting long-range interactions between the patches of digital qubits.

Further, method 1200 comprises creating 1203 multiple further arrays. These further arrays have an identical number of patches as the first array, which means that adding the further arrays does only affect one dimension of the quantum processor. In other words, the width of the quantum processor remains constant while further arrays are added, which is a significant advantage for facilitating manufacturing as it enables the wiring of all qubits. The number of arrays may depend on a desired error rate that is desired for a particular application. In that sense, an almost arbitrary reduction of the error rate can be achieved by making the quantum processor 100 longer while keeping the width constant. Since each array provides enough space for its own wiring, adding further arrays does not exacerbate the wiring problem.

The next step of method 1200 is connecting 1204 the multiple further arrays to the first array by the quantum bus, such as by extending the main bus 104 shown in FIG. 1. Finally, the method 1200 comprises creating 1205 control circuitry. The control circuitry controls the quantum processor by a first method of error correction on each of the patches connected by the bus. This reduces a relatively high error rate in the digital qubits to a relatively low error rate of each patch. The control circuitry further controls the quantum processor by a second method of error correction on the multiple patches to correct the relatively low error rate. The control circuitry may comprise ESR lines or other interconnects and controls. The control circuitry may further comprise signal generators or drivers as well as a classical computer that calculates the control pulses for performing the first and second methods of error control.

It is noted that the quantum processor 100 may be implemented in silicon and may be implemented on the same silicon die as a classical processor, such as an ARM processor core. In that sense, the quantum processor 100 constitutes extension hardware or a hardware accelerator to perform calculations that are practically impossible for classical computer to perform due to their complexity in a classical setting.

### Results

Simulations were performed on the Steane code implemented on this substrate, using a flag-qubit based fault-tolerant implementation. The results for the measured error rates are described in the graph in FIG. 10. An estimation of the logical error rate after one level of this implementation of Steane is:

p_{L}_{₂}=2.23×10⁴p_{L}_{₁}²−2.7×10⁶p_{L}_{₁}³+1.4×10⁸p_{L}_{₁}⁴−3×10⁹p_{L}_{₁}⁵

For p_{L}_{₁}=10⁻⁷ this gives P_{L}_{₂}: 2.23×10⁻¹⁰ with a single layer of Steane, and P_{L}_{₂}: 1.1×10⁻¹⁵ for a two layers of Steane concatenated together, using only an additional 2 ancillas. other codes such as the [[15,7,3]], or LDPC codes may be able to be used to obtain lower overheads from this stage. This shows that the resultant error rate is about the error rate of 10⁻¹⁵ mentioned above for solving the factoring of a 2048-bit number.

### Further Reduction in Lattice Width Through Highly Asymmetric Lower Level Surface Codes

In some of the above examples, the surface code is defined over a square patch of qubits, with a width of 2d-1 and a depth of 2d-1, where d is the distance of the code itself. In those examples, each dimension is responsible for independently correcting bit flip errors and phase flip errors. Logical errors in the planar surface code are caused when physical errors on the constituent qubits create chains that cross the lattice from left to right or from top to bottom. Which chains cause logical bit errors and which cause logical phase errors is defined with respect to the stabiliser orientation in the lattice.

Since the number of physical qubits in the horizontal dimension of the lattice (2d-1) is identical to the number in the vertical dimension of the lattice (2d-1) for a square planar code, the error correcting power for bit and phase errors is identical and specified by d.

In other examples, however, the planar surface code is asymmetrical by choosing two new distances, d_x and d_z, such that the physical lattice is now of dimension (W)idth x (D)epth (2d_x−1)×(2d_z−1). It is assumed that the logical chain operator defining the bit flip spans the width of the lattice. An asymmetric lattice is now more vulnerable to one type of error than the other. If d_x<d_z, the code has a smaller ability to tolerate logical bit flips, and visa versa if d_x>d_z the code has a smaller ability to tolerate phase errors.

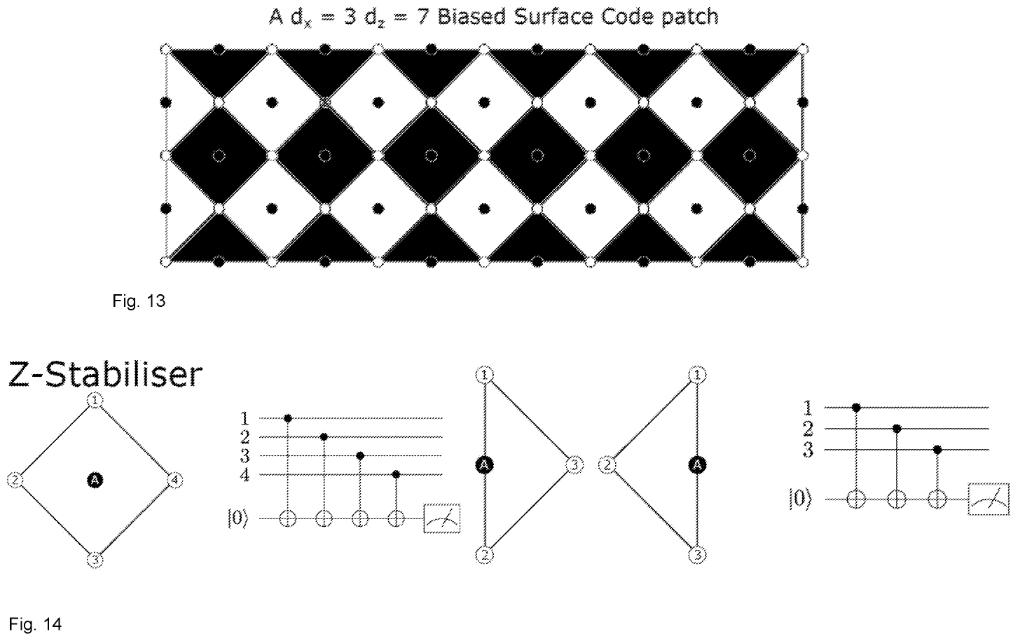

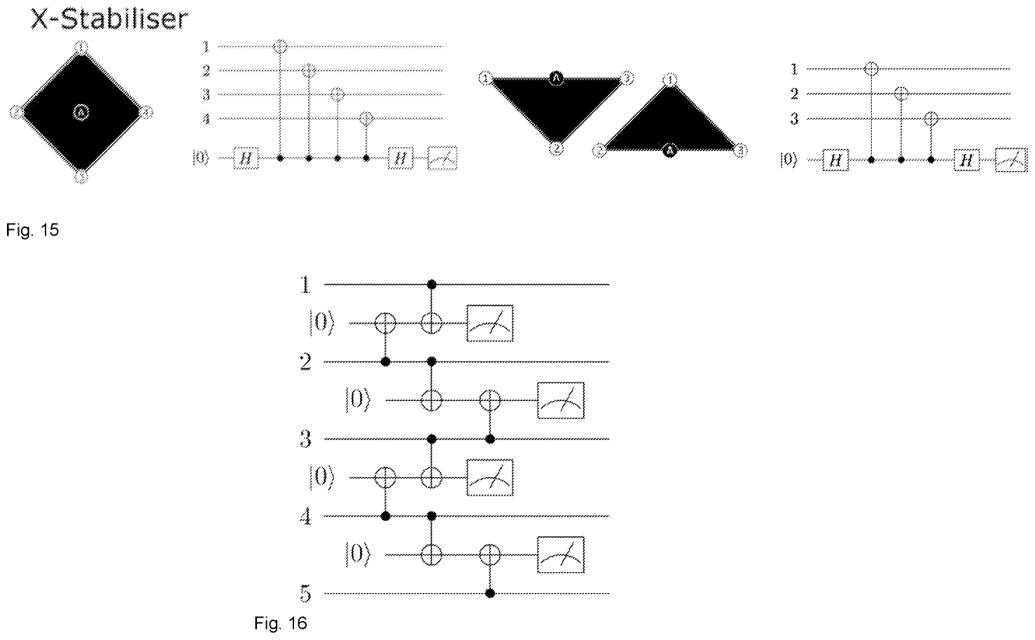

Shown in FIG. 13 is a rectangular planar surface code with a d_z=3 and a d_x=7, comprising an array of physical qubits 13 deep and 5 wide. The quantum circuits used to extract the two types of stabiliser operators are also shown in FIG. 14 and FIG. 15, respectively. These circuits are the same as for a square planar surface code.

In one example, the quantum processor comprises a long, thin rectangular surface code that is designed to minimise the width of the physical array, while still providing a minimal amount of error correction for, in the case of FIG. 13, phase (X) flips. The other dimension is deigned to heavily suppress one type of error, in FIG. 13 this is the bit (Z) flips, while in other examples the surface code heavily suppresses phase flips. The length of the physical array of qubits is not a constraint in this architecture and therefore encoded patches can have extremely large values of d_z, large enough to create an extremely large error bias at the logically encoded level.

The proposed architecture uses an asymmetric surface code structure to artificially create an error bias at the logical layer, which the architecture then exploits using much simpler error correcting code structures. Physical error rates for each of the constituent qubits can be considered to be below the fault-tolerant threshold of the surface code and are balanced (physical X errors are equally as likely as physical Z errors). For a logical qubit, logical Z errors are effectively non-existent and logical X errors have only been mildly suppressed. Once this is done, it is possible to concatenate effectively a classical repetition code on top of the logical surface code, designed to correct the now heavily dominant X errors. In other words, the first method of error correction mentioned above is now an asymmetric surface code while the second method of error correction is a repetition code.

The repetition code can correct against one of either bit-flip errors, or phase-flip errors (but not at the same time, hence the repetition code is not a full quantum code). In this code the logical |ϕ [symbol] =α|0 [symbol] +β|1 [symbol] state is encoded such that the 0 state is replaced with an N-fold product of zero's and the 1 state is replaced with an N-fold product of ones |ϕ [symbol] _{L}=α|0 . . . 0 [symbol] +β|1 . . . 1 [symbol] ). This encoding enables correction of bit flips in the logical state by comparing the parity of adjacent pairs of qubits. For a repetition code that is N-qubits long, the error correction distance is also N, meaning that up to (N−1)/2 errors can be corrected by examining the parity of N/2 adjacent pairs.

In between each logical qubit of the repetition code, and ancilla is used comparing the bit values between qubits (j) and (j+1). If an error has occurred, this measured parity will be odd.

In this code adjacent, the syndrome extraction of the repetition code can be performed very quickly, and in constant-time regardless of the code-distance of the repetition code. This fast syndrome extraction and high distance means that the threshold of the code is very high (˜50%). However the code cannot correct against both types of errors simultaneously. Other classical codes may also be used.

A new microarchitecture structure is to take advantage of these two independent properties to allow for a very small, physically fixed width array that can effectively implement fault-tolerant error correction.

The physical layer of qubits is arranged into a collection of rectangular patches that are encoded with a (d_x<<d_z) surface code. The minimal width that is viable, in one example technology, is d_x=3, corresponding to a physical width of the lattice of 5 physical qubits.

The length of the array is assumed to be arbitrary and can “encode” as many of these rectangular surface planar code patches as necessary by the computational algorithm.

On top of this surface code layer, the quantum processor performs an encoding into the repetition code. For the quantum processor to perform fault-tolerant error correction on this second layer, the total width of the array is extended by a factor of two, such that two planar surface codes are oriented in the vertical dimension of the lattice. This is used to make this second row or planar surface codes identical (in terms of the lower lying planar code error correction) and able to physically interact along the long boundary of the rectangular surface codes. Consequently, the minimum width used in this example for this is 5+5+1 physical qubits. 5 physical qubits for the width of each rectangular planar surface code and an additional one physical qubit as a spacer between the two logically encoded blocks. Again, the width of the entire array is assumed to be arbitrarily long

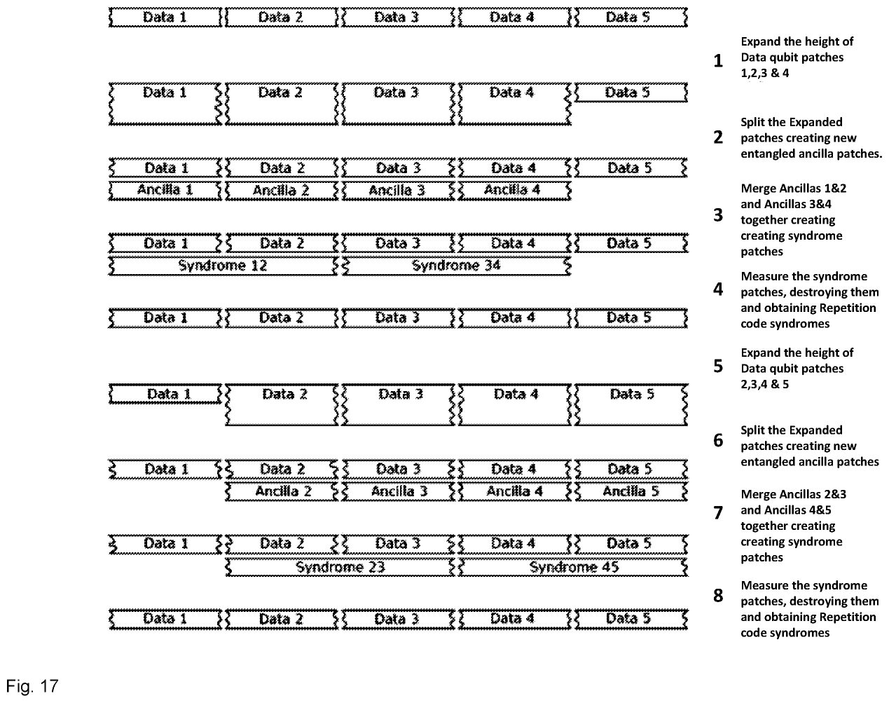

Error correction at the top layer of the code uses a set of lattice surgery enabled logic operations between the top row of planar surface code patches and the second ancilliary row. This sequence of operations is illustrated in FIG. 17.

In step one, each of the rectangular logical qubits in the repetition code is extended into the physical space of qubits in row two. This simply doubles the error correction strength from d_x=3 to d_x=6.

In step two the quantum processor performs a Lattice surgery split operation which generates an entangled state between the now two distinct rectangular surface code patches, each now reduced back to a d_x=3 planar surface code.

In step three the quantum processor merges operations between ancilliary qubits along their width. This now stores information related to the pairwise logical Z parity of the data qubits. The second row of planar surface code qubits now encode the syndrome information for the repetition code

Step four then measures each of these ancilliary planar surface code qubits, via measurement of all the physical constituent qubits. The measurement of these patches result in the classical syndrome information for the logical parity Z(j)Z(j+1)

As the repetition code uses measurement of all pairwise operations, this first block measures the non-overlapping pairs Z(1)Z(2) and Z(3)Z(4) etc. . . . . The quantum processor now repeats the sequence of operations again across the adjoining non-overlapping repetition code qubits Z(2)Z(3), Z(4)Z(5) etc. . . . . This completes the party checks of the repetition code.

Provided physical error rates are below the fault-tolerant threshold of the surface code (approximately 0.6%), the underlying surface code layer will produce a logical Z error rate that is <<1, while it will have a logical X error rate that is slightly >0.6% (the asymmetric code will effectively eliminate one type of quantum error while slightly amplifying the other).

Initialisation of the higher level repetition code is simply to prepare all planar surface code patches in the logical 0 state, this automatically creates the logical 0 state at the repetition code level.

The repetition code layer will then act as a repetition code, eliminating the X error that remain uncorrected from the surface code layer. This enables effective quantum error correction for both types of errors (X and Z) at the top logical layer while maintaining a fixed and small width for the entire array, which is a necessity for the microarchitecture.

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

1. A quantum processor comprising:
multiple patches of digital qubits; and
a quantum bus of digital qubits, configured to connect the multiple patches of digital qubits and to transmit quantum information constituting long-range interactions between the patches of digital qubits, wherein
the quantum processor is controlled by a first method of error correction on each of the patches connected by the bus to reduce a relatively high error rate in the digital qubits to a relatively low error rate of each patch, and by a second method of error correction on the multiple patches to correct the relatively low error rate.

2. The quantum processor of claim 1, wherein the quantum bus has a constant width of qubits.

3. The quantum processor of claim 1, wherein the multiple patches form multiple arrays of more than one patch each connected by the quantum bus.

4. The quantum processor of claim 3, wherein the multiple arrays are linear arrays.

5. The quantum processor of claim 4, wherein each linear array has an identical width.

6. The quantum processor of claim 5, wherein each linear array has an array width defined by one of the multiple patches and the quantum bus, the array width being 15 or 20.

7. The quantum processor of claim 4, wherein each linear array has an array length defined by more than one of the multiple patches and the quantum bus, the array length being 120 or 160.

8. The quantum processor of claim 1, further comprising an area between the multiple patches comprising connections to the digital qubits of the multiple patches.

9. The quantum processor of claim 1, wherein the digital qubits of the bus are controlled by the first method of error correction.

10. The quantum processor of claim 1, wherein the first method of error correction comprises a surface code.

11. The quantum processor of claim 1, wherein the second method of error correction comprises a block code.

12. (canceled)

13. (canceled)

14. (canceled)

15. (canceled)

16. (canceled)

17. (canceled)

18. The quantum processor of claim 1, wherein the patches are rectangular and have a first dimension that is greater than a second dimension to reduce the error rate of a first type of error, associated with the first dimension, to a greater degree than the error rate of a second type of error, associated with the second dimension.

19. The quantum processor of claim 18, wherein the first method of error correction is an asymmetric surface code to reduce the error rate of the first type of error to a greater degree than the error rate of the second type of error.

20. The quantum processor of claim 19, wherein the second method of error correction is a repetition code to reduce the error rate of the second type of error.

21. The quantum processor of claim 18, wherein the second method of error correction reduces the error rate of only the second type of error.

22. The quantum processor of claim 18, wherein the first type of error is one of a bit flip error and a phase flip error and the second type of error is another one of a bit flip error and a phase flip error.

23. A method for operating a quantum processor, the quantum processor comprising multiple patches of digital qubits and a quantum bus of digital qubits, configured to connect the multiple patches of digital qubits and to transmit quantum information constituting long-range interactions between the patches of digital qubits, the method comprising:
applying a first method of error correction to each of the patches connected by the bus to reduce a relatively high error rate in the digital qubits to a relatively low error rate of each patch; and
applying a second method of error correction to the multiple patches to correct the relatively low error rate.

24. A method for manufacturing a quantum processor, the method comprising:
creating multiple patches of digital qubits to form a first array of a number of patches;
connecting the multiple patches of the first array by a quantum bus of digital qubits, configured to connect the multiple patches of digital qubits and to transmit quantum information constituting long-range interactions between the patches of digital qubits;
creating multiple further arrays having an identical number of patches as the first array;
connecting the multiple further arrays to the first array by the quantum bus;
creating control circuitry to control the quantum processor by a first method of error correction on each of the patches connected by the bus to reduce a relatively high error rate in the digital qubits to a relatively low error rate of each patch, and by a second method of error correction on the multiple patches to correct the relatively low error rate.

25. The method of claim 24, wherein a number of the multiple further arrays is based on a desired error rate after correction of the relatively low error rate.

26. The quantum processor of claim 1, wherein the relatively low error rate is less than 10⁻⁵ or the relatively low error rate is more than 10⁻⁸ or correcting the relatively low error rate results in a corrected error rate of less than 10⁻⁹.
